(19) United States
(12) Patent Application Publication
(10) Pub. No.: US 2017/0323923 A1
(43) Pub. Date: Nov. 9, 2017

(54) PHOTON COUNTING DEVICES

(71) Applicant: General Electric Company, Schenectady, NY (US)

(72) Inventor: Jongwoo Choi, Niskayuna, NY (US)

(21) Appl. No.: 15/268,646

(22) Filed: Sep. 19, 2016

Related U.S. Application Data
(63) Continuation-in-part of application No. 15/145,825, filed on May 4, 2016.

(51) Int. Cl. H01L 27/146; H01L 31/0224; H01L 31/0216; H01L 31/115; H01L 31/0296

(52) U.S. Cl. CPC H01L 27/14659; H01L 31/115; H01L 31/02966; H01L 27/1462; H01L 31/02161; H01L 31/022408

(57) ABSTRACT

Described herein are semiconductor materials suitable for direct conversion of ionizing radiation to electron hole pairs. The material described herein have improved high-flux photon counting performance and lower photocurrent leakage compared to typically used semiconductors.

### CROSS REFERENCE TO RELATED APPLICATIONS

This application is a continuation in part of U.S. patent application Ser. No. 15/145,825 titled “Metal Oxide Interface Passivation For Photon Counting Devices” filed May 4, 2016 which is incorporated herein by reference in its entirety.

### BACKGROUND

This disclosure relates generally to detectors used in photon counting devices.

A semiconductor radiation detector may be used to detect photons for medical imaging systems. In devices based on direct detection, the photon counting device typically comprises a direct-conversion type semiconductor made of cadmium telluride (CdTe), cadmium zinc telluride (CdZnTe), or the like. Photons of ionizing radiation, e.g., X-ray or gamma ray radiation, are absorbed by the semiconductor of the detector and generate measurable electric signals; there is no need to convert the ionizing radiation into visible light with a scintillator, i.e., the detector is a direct mode detector.

X-rays or gamma rays interact with atoms in the semiconductor to create electron/hole pairs. In order to facilitate the electron/hole collection process in the detector, a +500 volts potential is applied. This voltage is too high for operation at room temperature for small bandgap semiconductors such as germanium or if the resistivity is not high enough (e.g. <10⁸ Ω-cm), as it will cause excessive leakage, and eventually a breakdown. Typically, the detector in the X-ray imaging apparatus is cooled, thereby reducing leakage current and permitting the high bias voltage. The material that a semiconductor is made of has an effect on the photon counting performance of the detector and also has an effect on the leakage current. The more the leakage current, the lower is the signal to noise ratio of the detector.

There is a need in the field for improved materials for direct conversion type layers for semiconductors in photon counting devices which can improve the performance of the detectors and reduce leakage of photocurrent. There is a need in the field for improving the signal to noise ratio of X-ray detectors.

### BRIEF DESCRIPTION

Described herein are semiconductor materials having improved high-flux photon counting performance and lower photocurrent leakage compared to typically used semiconductors. The materials described herein are suitable for formation of direct conversion layers in photon counting devices, and are suitable for use in X-ray imaging devices, and other imaging devices.

### DRAWINGS

These and other features, aspects, and advantages of the present invention will become better understood when the following detailed description is read with reference to the accompanying drawings in which like characters represent like parts throughout the drawings, wherein:

FIG. 1 shows a schematic representation of an example of a photon counting device, an X-ray imaging device.

FIG. 2 shows a comparison of X-ray photon counting performance of a conventional semiconductor versus a semiconductor described herein.

### DETAILED DESCRIPTION

Described herein are materials for reducing leakage current and/or improving photon counting performance in high flux photon counting devices, e.g., direct mode X-ray detectors. Typically, semiconductor crystal layers in scintillator based detectors are thin. However, direct mode detectors comprise direct conversion layers that are thicker than the semiconductor layers in scintillator based detectors. The materials described herein are suitable for formation of direct conversion layers of more than 1 mm thickness for use in photon counting devices, including high flux photon counting devices, and are suitable for use in X-ray imaging devices, and other imaging devices.

Though the discussion focuses primarily on detectors for measurement of X-ray flux levels or energy levels in a medical imaging context, non-medical applications such as security and screening systems and non-destructive detection systems are well within the scope of the present technique. Further the detector structure and arrangement may be used in, or in conjunction with, computed tomography systems, and in other systems, such as other radiography systems, tomosynthesis systems, mammography systems, C-arm angiography systems and so forth.

The singular forms “a”, “an” and “the” include plural references unless the context clearly dictates otherwise. As used herein, the term “or” is not meant to be exclusive, and refers to at least one of the referenced components being present and includes instances in which a combination of the referenced components may be present, unless the context clearly dictates otherwise.

Approximating language, as used herein throughout the specification and claims, may be applied to modify any quantitative representation that could permissibly vary without resulting in a change in the basic function to which it is related. Accordingly, a value modified by a term or terms, such as “about”, and “substantially” are not to be limited to the precise value specified. In some instances, the approximating language may correspond to the precision of an instrument for measuring the value. Here and throughout the specification and claims, range limitations include all the sub-ranges contained therein unless context or language indicates otherwise.

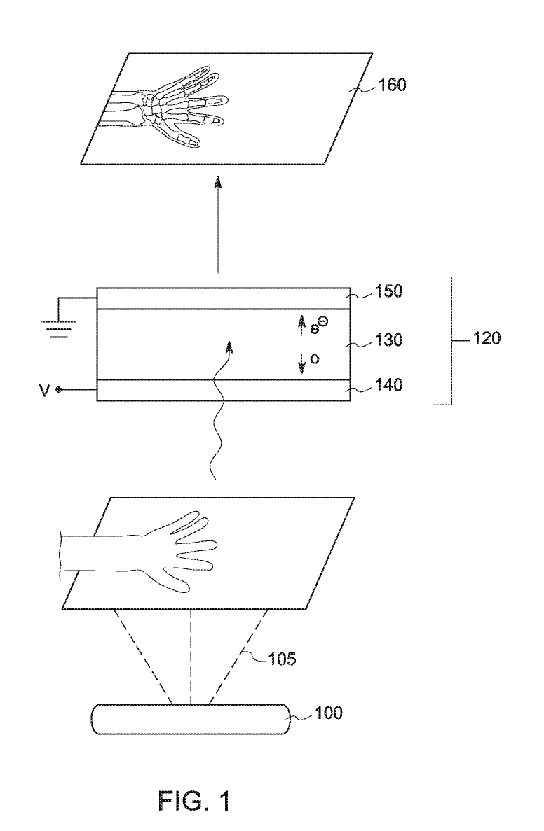

FIG. 1 describes a typical set up for a photon counting device, specifically, an X-ray imaging medical device. An X-ray source 100 generates radiation 105 which passes through an object 110 and is received on the detector 120 which comprises a semiconductor 130, a cathode 140, and an anode 150. The resulting current is converted to an image 160.

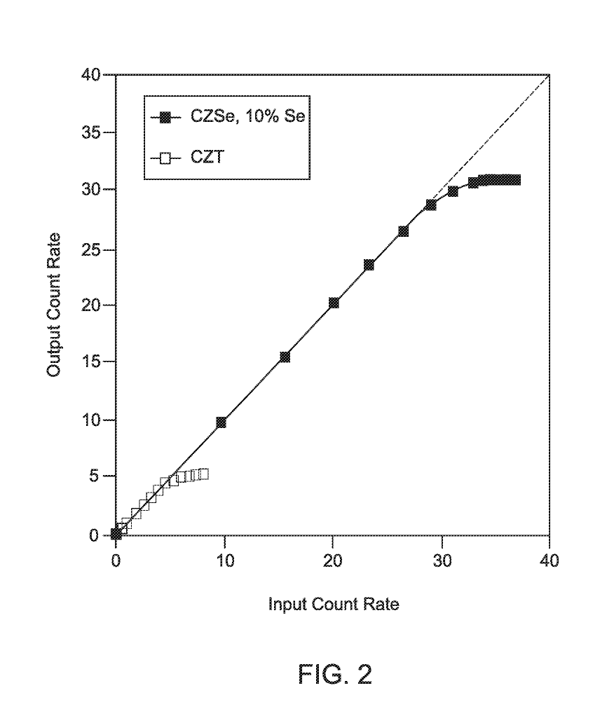

FIG. 2 shows a comparison of X-ray photon counting performance of a CZT semiconductor (open symbols) versus a photon counting device described herein, i.e., a CZTSe, 10% Se (solid symbols) semiconductor. Both crystals were grown in similar conditions. The data in FIG. 2 shows that adding Se to CZT crystals grown in similar conditions helps improve X-ray photon counting performance. Without being bound by any theory, the better performance of high-flux photon counting is believed to be due to the low polarization of the electric fields inside the crystal and decrease of the deep level (˜1 eV) band that is believed to be associated with structural defects in conventional crystals.

Provided herein are photon counting devices (including high flux photon counting devices) comprising a direct conversion layer of at least 1 mm thickness and comprising a Group II-VI semiconductor layer of Formula I:

A Te_{y}Se_{(1-y)} I;

wherein A is Cd, Zn, Hg, Mg, or Mn, or a combination thereof; and y ranges from 0 to 1. In some embodiments, A is Cd or Zn. In some embodiments, A is Cd, Zn or Hg.

As used herein, a “direct conversion layer” refers to a semiconductor layer in which ionizing radiation (e.g., X-rays or gamma rays) interacts with atoms in the semiconductor layer to create electron/hole pairs which are collected/measured by the detector, i.e., there is no intervening step in which the ionizing radiation interacts with a scintillator which converts the ionizing radiation to visible light. Typically, the direct conversion layers described herein are greater than 1 mm in thickness, optionally from about 1 mm to about 3 mm in thickness, from about 1 mm to about 5 mm in thickness, or from about 1 mm to about 10 mm thickness.

Group II-VI semiconductors include, and are not limited to, II-VI ternary alloy semiconductors comprising cadmium zinc telluride (CdZnTe, CZT), mercury cadmium telluride (HgCdTe), mercury zinc telluride (HgZnTe) and the like. Also contemplated are II-VI semiconductors comprising Cadmium selenide (CdSe), Cadmium telluride (CdTe), Zinc selenide (ZnSe), Zinc telluride (ZnTe) and combinations thereof.

Cadmium zinc telluride, (CdZnTe) or CZT, is an alloy of cadmium telluride and zinc telluride. It is used in radiation detectors, photorefractive gratings, electro-optic modulators, and solar cells. HgCdTe or mercury cadmium telluride (also cadmium mercury telluride, MCT or CMT) is an alloy of CdTe and HgTe. The amount of cadmium (Cd) in the alloy can be chosen to tune the optical absorption of the material to a desired infrared wavelength. Mercury zinc telluride (HgZnTe, MZT) is an alloy of mercury telluride and zinc telluride. It is used in infrared detectors and arrays for infrared imaging and infrared astronomy.

In some embodiments, a photon counting device described herein comprises a direct conversion semiconductor layer wherein A is CdₓZn₍₁₋ₓ₎, and x ranges from 0 to 1. In some of such embodiments, x ranges from about 0.5 to about 0.9. In some other of such embodiments, x is about 0.9.

In some embodiments, a photon counting device described herein comprises a direct conversion semiconductor layer of formula A Te_{y}Se_{(1-y)} wherein y ranges from 0.99 to about 0.8, or wherein y is about 0.9.

In one group of embodiments for a photon counting device described herein, the Group II-VI semiconductor is a CZT semiconductor wherein up to about 10% of Te is replaced with Se.

In some of such embodiments, the direct conversion layer for a photon counting device described herein comprises a semiconductor of the following Formula:

Cd_{(0.9)}Zn_{(0.1)}Te_{(0.9)}Se_{(0.1)}.

In general, for the embodiments described above, the Group II-VI semiconductor layer is located between a cathode electrode and an anode electrode.

In one group of embodiments, a photon counting device described herein further comprises a metal oxide layer deposited between the Group II-VI semiconductor layer and the cathode electrode, wherein the metal oxide is selected from the group consisting of aluminum oxide (Al₂O₃), gallium oxide (Ga₂O₃), hafnium oxide (HfO₂), zirconium oxide (ZrO₂), magnesium oxide (MgO) and combinations thereof. In some of such embodiments, the metal oxide comprises Al₂O₃, MgO, or a combination thereof. In some specific embodiments, the metal oxide comprises Al₂O₃.

Also provided herein are X-ray imaging devices comprising photon counting devices (including high flux photon counting devices) having a direct conversion layer of at least 1 mm thickness and comprising a Group II-VI semiconductor layer of Formula I:

A Te_{y}Se_{(1-y)} I;

wherein A is Cd, Zn, Hg, Mg, or Mn, or a combination thereof; and y ranges from 0 to 1. In some embodiments, A is Cd or Zn. In some embodiments, A is Cd, Zn or Hg.

One or more radiation detectors formed in accordance with various embodiments described herein may be used to image an object, such as a human individual, another living creature besides a human individual, or inanimate objects, such as, but not limited to, luggage, shipping containers, and/or the like. However, in other embodiments, no image is generated or formatted and other data is acquired by the radiation detectors, such as spectral response data.

It should be noted that radiation detectors formed in accordance with various embodiments described herein may be used, for example, in imaging systems to reconstruct or render an image. However, the term “reconstructing” or “rendering” an image or data set is not intended to exclude embodiments in which data representing an image is generated, but a viewable image is not. Therefore, when used, “image” or “imaging” broadly refers to both viewable images and data representing a viewable image that may be generated from data acquired by a radiation detector of one or more embodiments.

### Examples

### Materials:

CZT family crystals and Selenium-CZT crystals were grown by the Bridgman method. Wafers were cut and polished up to 1 μm using alumina slurry. The surface of the polished wafers was treated with hydrogen peroxide (H₂O₂), followed by metal electrode deposition. Optionally, a passivation layer was deposited between the wafer and the cathode electrode as described in U.S. patent application Ser. No. 15/145,825, which disclosure is incorporated herein by reference.

### Testing:

The photon counting tests were done with the x-ray flux at 140 kVp/6 mA (input count rate flux=37 (×10⁶) X-ray/s/mm²) and 10 msec of integration time. Bias voltage of 2000 V was applied across the device. FIG. 2 shows a comparison of X-ray photon counting performance of a CZT crystal versus a selenium incorporated CZT crystal. The data in FIG. 2 shows that adding Se to CZT crystals grown in similar conditions helps improve X-ray photon counting performance of a direct conversion semiconductor layer.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A photon counting device comprising
a direct conversion layer of at least 1 mm thickness and comprising a Group II-VI semiconductor layer of Formula I:
A Te_{y}Se_{(1-y)} I;
wherein
A is Cd, Zn, Hg, Mg, or Mn, or a combination thereof;
and
y ranges from 0 to 1.

2. The photon counting device of claim 1 wherein A is CdₓZn₍₁₋ₓ₎, and x ranges from 0 to 1.

3. The photon counting device of claim 2, wherein x is about 0.9.

4. The photon counting device of claim 1, wherein y is about 0.9.

5. The photon counting device of claim 1, wherein the Group II-VI semiconductor is a CZT semiconductor wherein up to about 10% of Te is replaced with Se.

6. The photon counting device of claim 1, wherein Formula I is
Cd_{(0.9)}Zn_{(0.1)}Te_{(0.9)}Se_{(0.1)}.

7. The photon counting device of claim 1, wherein the Group II-VI semiconductor layer is located between a cathode electrode and an anode electrode.

8. The photon counting device of claim 7, further comprising a metal oxide layer deposited between the Group II-VI semiconductor layer and the cathode electrode, wherein the metal oxide is selected from the group consisting of aluminum oxide (Al₂O₃), gallium oxide (Ga₂O₃), hafnium oxide (HfO₂), zirconium oxide (ZrO₂), magnesium oxide (MgO) and combinations thereof.

9. The photon counting device of claim 8, wherein the metal oxide comprises Al₂O₃, MgO, or a combination thereof.

10. The photon counting device of claim 8, wherein the metal oxide comprises Al₂O₃.

11. An X-ray imaging device comprising a photon counting device of claim 1.
